(19) United States
(12) Patent Application Publication
(10) Pub. No.: US 2010/0072890 A1
(43) Pub. Date: Mar. 25, 2010

(54) INORGANIC ELECTROLUMINESCENT DEVICE AND DISPLAY APPARATUS EMPLOYING THE SAME

(75) Inventors: Min-jong BAE, Yongin-si (KR); Shang-hyeun PARK, Yongin-si (KR); Byoung-lyong CHOI, Seoul (KR)

Correspondence Address: CANTOR COLBURN, LLP, 20 Church Street, 22nd Floor, Hartford, CT, 06103, US

(73) Assignee: SAMSUNG ELECTRONICS CO., LTD., Suwon-si (KR)

(21) Appl. No.: 12/550,581

(22) Filed: Aug. 31, 2009

(30) Foreign Application Priority Data
Sep. 22, 2008 (KR) 10-2008-0092924

(51) Int. Cl. H05B 33/00; H01L 21/02

(52) U.S. Cl. 313/509; 438/29; 257/E21.002

(57) ABSTRACT

An inorganic electroluminescent device includes; a conductive layer, a fluorescent material layer disposed on a surface of the conductive layer, a dielectric material layer disposed on a surface of the conductive layer substantially opposite to the surface on which the fluorescent material layer is disposed, a first electrode disposed on the fluorescent layer, and a second electrode disposed on the dielectric material layer.

### CROSS-REFERENCE TO RELATED APPLICATION

This application claims priority to Korean Patent Application No. 10-2008-0092924, filed on Sep. 22, 2008, and all the benefits accruing therefrom under 35 U.S.C. §119, the contents of which in its entirety are herein incorporated by reference.

### BACKGROUND

1. Field

One or more exemplary embodiments relate to an inorganic electroluminescent device and a display apparatus employing the same.

2. Description of the Related Art

Electroluminescent devices use a phenomenon wherein electrical energy is converted to light energy, and such electroluminescent devices are used as lamp-type light sources or may be used in active-luminescent display devices. Electroluminescent devices can be divided into two different types according to the materials that make up the luminescent layers of the electroluminescent device: organic electroluminescent devices and inorganic electroluminescent devices. Inorganic electroluminescent devices include powder-type inorganic electroluminescent devices, which are widely used as light sources for keypads for cellular phones, billboards, simple medical equipments, and various other devices. However, it is difficult to embody a display apparatus using inorganic electroluminescent devices due to crosstalk occurring when the display apparatus employing inorganic electroluminescent devices is driven.

### SUMMARY

One or more exemplary embodiments provide inorganic electroluminescent devices reducing crosstalk when a display apparatus is driven.

One or more exemplary embodiments provide a display apparatus employing inorganic electroluminescent devices, such that crosstalk is reduced when the display apparatus is driven.

Additional aspects, advantages and features will be set forth in part in the description which follows and, in part, will be apparent from the description, or may be learned by practice of the invention.

One or more exemplary embodiments may include an inorganic electroluminescent device including; a conductive layer, a fluorescent material layer disposed on a surface of the conductive layer, a dielectric material layer disposed on a surface of the conductive layer substantially opposite to the surface on which the fluorescent material layer is disposed, a first electrode disposed on the fluorescent material layer, and a second electrode disposed on the dielectric material layer.

In one exemplary embodiment, at least one of the first electrode and the second electrode may be a transparent electrode.

In one exemplary embodiment, the conductive layer may be formed of one of a conductive polymer, silver paste, carbon nano tube (“CNT”) paste or a combination thereof.

In one exemplary embodiment, an interface between the conductive layer and the dielectric material layer may have a substantially planar surface.

One or more exemplary embodiments may include a display apparatus including a first electrode array including a plurality of first electrodes arranged in a stripe shape, a second electrode array including a plurality of second electrodes arranged in a stripe shape extending substantially perpendicular to the plurality of first electrodes of the first electrode array, a conductive layer interposed between the first electrode array and the second electrode array, a fluorescent material layer interposed between the conductive layer and the first electrode array, and a dielectric material layer interposed between the conductive layer and the second electrode array.

### BRIEF DESCRIPTION OF THE DRAWINGS

These and/or other aspects, advantages, and features of exemplary embodiments of the invention will become apparent and more readily appreciated from the following description of the embodiments, taken in conjunction with the accompanying drawings of which:

FIG. 1 is a schematic diagram illustrating an exemplary embodiment of an inorganic electroluminescent device according to the present invention;

FIG. 2 is schematic a diagram illustrating another exemplary embodiment of an inorganic electroluminescent device according to the present invention;

FIG. 3 is a schematic diagram showing a comparative embodiment of an inorganic electroluminescent device for comparing to an exemplary embodiment of an inorganic electroluminescent device according to the present invention;

FIG. 4 is a graph showing a comparison of brightness changes with respect to driving voltages between an exemplary embodiment of an inorganic electroluminescent device according to the present invention and the comparative embodiment of an inorganic electroluminescent device; and

FIG. 5 is a schematic diagram illustrating an exemplary embodiment of a display apparatus according to the present invention.

### DETAILED DESCRIPTION

The invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

All methods described herein can be performed in a suitable order unless otherwise indicated herein or otherwise clearly contradicted by context. The use of any and all examples, or exemplary language (e.g., “such as”), is intended merely to better illustrate the invention and does not pose a limitation on the scope of the invention unless otherwise claimed. No language in the specification should be construed as indicating any non-claimed element as essential to the practice of the invention as used herein.

Hereinafter, an exemplary embodiment of an inorganic electroluminescent device and an exemplary embodiment of a display apparatus employing the same will be described in detail. The present exemplary embodiment of an inorganic electroluminescent device includes a conductive layer, a fluorescent material layer disposed on one surface of the conductive layer, and a dielectric material layer disposed on the other surface of the conductive layer.

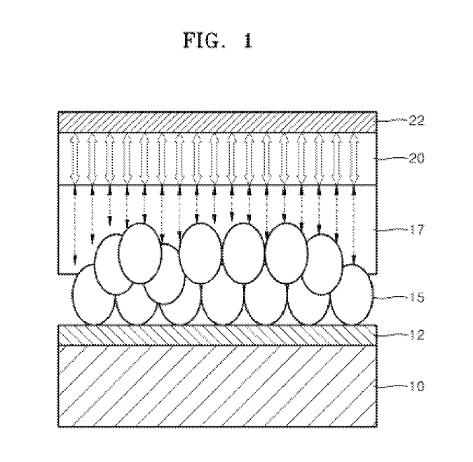

FIG. 1 is a schematic diagram illustrating an exemplary embodiment of an inorganic electroluminescent device.

Referring to FIG. 1, the present exemplary embodiment of an inorganic electroluminescent device includes a fluorescent material layer 15 disposed on a first electrode 12, a conductive layer 17 disposed on the fluorescent material layer 17, a dielectric material layer 20 disposed on the conductive layer 17, and a second electrode 22 disposed on the dielectric material layer 20. Exemplary embodiments include configurations wherein a substrate 10 may be disposed below the first electrode 12. Exemplary embodiments include configurations wherein the fluorescent material layer 15 may be formed as powders. Exemplary embodiments include configurations wherein at least one of the first electrode 12 and the second electrode 22 may be formed as an indium tin oxide (“ITO”) transparent electrode, and an electrode through which luminescent light generated by the fluorescent material layer 15 travels may be formed as a transparent electrode. The present exemplary embodiment of an inorganic electroluminescent device shown in FIG. 1 is a bottom view type electroluminescent device wherein luminescent light is transmitted in a direction toward the substrate 10, and the first electrode 12 may be formed as a transparent electrode.

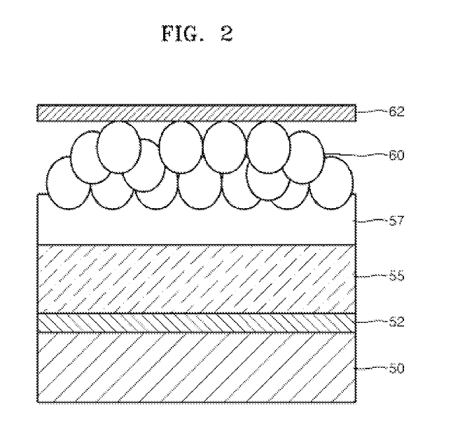

FIG. 2 is schematic a diagram illustrating another exemplary embodiment of an inorganic electroluminescent device according to the present invention;

Referring to FIG. 2, the exemplary embodiment of an inorganic electroluminescent device shown in FIG. 2 is a top view type electroluminescent device including a first electrode 52 disposed on a substrate 50, a dielectric material layer 55 disposed on the first electrode 52, a conductive layer 57 disposed on the dielectric material layer 55, and a fluorescent material layer 60 disposed on the conductive layer 57. A second electrode 62 is disposed on the fluorescent material layer 60. In the present exemplary embodiment, the second electrode 62 may be formed as a transparent electrode. Furthermore, exemplary embodiments include configurations wherein both of the first electrode 52 and the second electrode 62 may be formed as transparent electrodes.

According to the above described exemplary embodiments, the conductive layers 17 and 57 are interposed between the fluorescent material layers 15 and 60 and the dielectric material layers 20 and 55, respectively, and interfaces between the conductive layers 17 and 57 and the dielectric material layers 20 and 55 are formed to have even, substantially planar, surfaces. Exemplary embodiments of the conductive layers 17 and 57 are formed of a conductive material. Exemplary embodiments of the conductive layers 17 and 57 may be formed of at least one of a conductive polymer, silver paste, carbon nano tube (“CNT”) paste, combinations thereof, or other materials having similar characteristics. Exemplary embodiments include configurations wherein the conductive layers 17 and 57 may be formed using methods such as screen printing, spin coating, electroplating, spraying or other similar methods. Furthermore, exemplary embodiments of the fluorescent material layers 15 and 60, the dielectric material layers 20 and 55, the first electrodes 12 and 52, and the second electrodes 22 and 62 may be formed using the screen printing method, or other similar methods.

Next, operations of an exemplary embodiment of an inorganic electroluminescent device will be described. When a voltage is applied to the inorganic electroluminescent device, an electric field is generated between the first electrode 12 or 52 and the second electrode 22 or 62. Electrons, which exit from the dielectric material layer 20 or 55, are accelerated by the electric field and collide against a fluorescent material in the fluorescent material layer 15 or 60.

The thickness of the dielectric material layer 20 or 55 in exemplary embodiments of the inorganic electroluminescent device is substantially constant, and an interface between the dielectric material layer 20 or 55 and the conductive layer 17 or 57 is formed to have an even, substantially planar, surface. Thus, the electric field is evenly generated in the dielectric material layer 20 or 55. Since the conductive layer 17 or 57 is not affected by the electric field, the electric field generated in the dielectric material layer 20 or 55 is directly applied to the fluorescent material layer 15 or 60 as if the conductive layer 17 or 57 was not present. Therefore, an electric field generated in the dielectric material layer 20 or 55 is applied to the fluorescent material layer 15 or 60 substantially simultaneously with the application of the electric field across the first and second electrodes 12 and 22 and 52 and 62, respectively. In one exemplary embodiment, electrons are injected from the dielectric material layer 20 or 55 into the fluorescent material layer 15 or 60 substantially simultaneously with the application of an electric field to the first and second electrodes 12 and 22 and 52 and 62, respectively. Thus, the fluorescent material layer 15 or 60 begins to emit light when the electric field exceeds a predetermined threshold voltage, and the fluorescent material layer 15 or 60 does not emit light if electric field is below the threshold voltage.

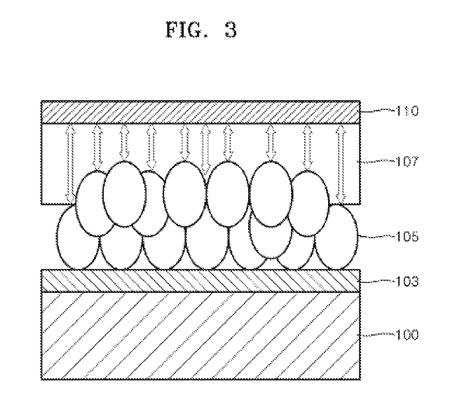

For an easier explanation of the operations of the exemplary embodiment of an inorganic electroluminescent device, a comparative embodiment of an inorganic electroluminescent device is shown in FIG. 3. The inorganic electroluminescent device shown in FIG. 3 includes a substrate 100, a first electrode 103, a fluorescent material layer 105, a dielectric material layer 107, and a second electrode 110, wherein no conductive layer is interposed between the fluorescent material layer 105 and the dielectric material layer 107.

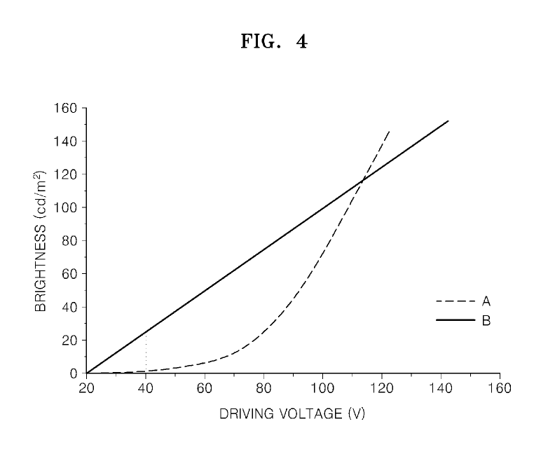

Since the fluorescent material layer 105 is formed as a powder including a plurality of granules as shown in FIG. 3, an interface between the fluorescent material layer 105 and the dielectric material layer 107 has an uneven surface. Due to the uneven nature of the dielectric material layer 107 surface, the thickness of the dielectric material layer 107 is not constant. Thus, when voltages are applied to the first electrode 103 and the second electrode 110, an electric field formed in the dielectric material layer 107 is non-uniform, and thus electric fields affecting each of the individual granules of the powder forming the fluorescent material layer are not uniform. Therefore, the individual granules of the fluorescent material layer 105 do not emit a uniform amount of light, and light is sequentially emitted from the granules of the fluorescent material layer closest to the top surface of the dielectric material layer 107 to the fluorescent material farthest from the top surface of the dielectric material layer 107. Therefore, as shown in FIG. 4, the brightness of the comparative embodiment of an inorganic electroluminescent device with respect to the driving voltage changes in a linear fashion in the comparative embodiment (B).

When the comparative embodiment is employed in a display apparatus, crosstalk occurs. In a display apparatus in which the pixels thereof include the comparative embodiment of an inorganic electroluminescent device shown in FIG. 3, when the driving voltage is applied to a predetermined pixel, the pixels adjacent to the predetermined pixel are also affected by the driving voltage. In other words, the driving voltage is also partially applied to the pixels adjacent to the predetermined pixel. In the embodiment wherein a driving voltage of 120 V is applied to a predetermined pixel, voltages of approximately 40 V may be applied to the pixels adjacent to the predetermined pixel. In such a situation, if the brightness changes in a linear fashion with respect to the driving voltages, undesired pixels emit light even when only a voltage of 40 V is applied thereto, and thus undesirable crosstalk occurs.

In contrast, in the above-described exemplary embodiments of inorganic electroluminescent devices, an electric field is applied to the fluorescent material layer 15 or 60 substantially simultaneously as the application of the electric field due to the conductive layer 17 or 57 interposed between the fluorescent material layer 15 or 60 and the dielectric material layer 20 or 55. Thus, the brightness of light emitted by the fluorescent material layer 15 or 60 changes exponentially with respect to the driving voltages applied thereto as indicated by line A in FIG. 4. In other words, the fluorescent material layer 15 or 60 emits light with respect to the voltage exceeding a predetermined threshold. In one exemplary embodiment, when a driving voltage of 120 V is applied to a pixel and a voltage of approximately 40 V is applied to an adjacent pixel, a fluorescent material layer of the adjacent pixel does not emit light, and thus an undesirable crosstalk may be reduced or effectively eliminated. In one exemplary embodiment, the threshold of the driving voltage at which a fluorescent material layer begins to emit light may be controlled by changing the thickness of a dielectric material layer.

Since the exemplary embodiment of an inorganic electroluminescent device can reduce crosstalk as described above, an exemplary embodiment of a display apparatus employing the exemplary embodiment of an inorganic electroluminescent device can be constructed. Next, the exemplary embodiment of a display apparatus according to the present invention will be described.

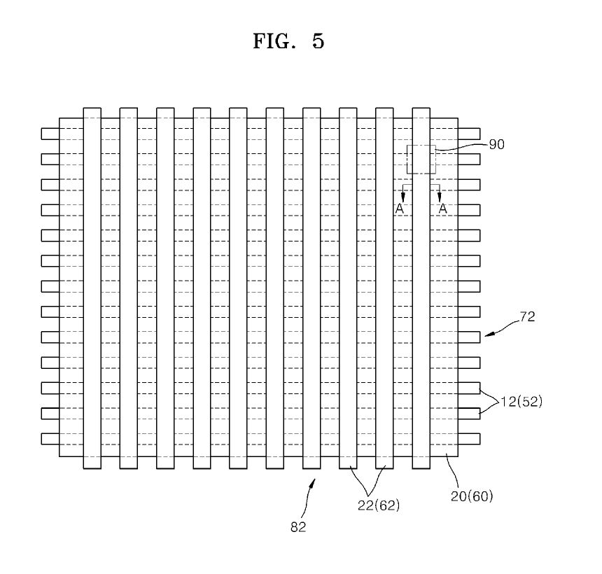

FIG. 5 illustrates an exemplary embodiment of a display apparatus according to the present invention. Referring to FIGS. 1, 2, and 5, the display apparatus includes a first electrode array 72 in which a plurality of first electrodes 12 or 52 are arranged in stripe shapes and a second electrode array 82 in which a plurality of second electrodes 22 or 62 are arranged in stripe shapes. The first electrode array 72 and the second electrode array 82 are arranged to be substantially perpendicular to one another. In one exemplary embodiment, a pixel 90 may be formed at each intersection where the first electrodes 12 or 52 and the second electrodes 22 or 62 cross over each other. According to a cross-sectional view of the pixel 90, obtained along a line A-A, each of the pixels 90 has a layer structure of the exemplary embodiment of an inorganic electroluminescent device shown in FIG. 1 or FIG. 2. As shown in FIG. 1, the conductive layer 17 may be interposed between the first electrode 12 and the second electrode 22, the fluorescent material layer 15 may be interposed between the conductive layer 17 and the first electrode 12, and the dielectric material layer 20 may be interposed between the conductive layer 17 and the second electrode 22. Referring to FIG. 2, the conductive layer 57 may be interposed between the first electrode 52 and the second electrode 62, the dielectric material layer 55 may be interposed between the first electrode 52 and the conductive layer 57, and the fluorescent material layer 60 may be interposed between the second electrode 62 and the conductive layer 57. Furthermore, exemplary embodiments include configurations wherein the substrate 10 or 50, shown in FIGS. 1 and 2, may be disposed below the first electrode array 72.

In the present exemplary embodiment of a display apparatus, a voltage is selectively applied to one of the first electrode array 72 and the second electrode array 82 to apply a voltage to a predetermined pixel. When a voltage is applied to the predetermined pixel, an electric field is applied to the predetermined pixel, and the fluorescent material layer 15 or 60 of the predetermined pixel emits light, and thus, an image is displayed.

An exemplary embodiment of a display apparatus according to the present invention includes a conductive layer disposed between a dielectric material layer and a fluorescent material layer such that an electric field is applied to the fluorescent material layer substantially simultaneously as a driving voltage is applied to the display apparatus. Thus, crosstalk in adjacent pixels is inhibited. Accordingly, a display apparatus can be driven. Although descriptions of the exemplary embodiments above are regarding a passive matrix structure, alternative exemplary embodiments may also be applied to an active matrix structure.

As described above, according to the one or more of the above exemplary embodiments, an exemplary embodiment of a display apparatus employing an exemplary embodiment of an inorganic electroluminescent device, which reduces crosstalk, can be embodied.

It should be understood that the exemplary embodiments described therein should be considered in a descriptive sense only and not for purposes of limitation. Descriptions of features or aspects within each embodiment should typically be considered as available for other similar features or aspects in other embodiments.

What is claimed is:

1. An inorganic electroluminescent device comprising:
a conductive layer;
a fluorescent material layer disposed on a surface of the conductive layer;
a dielectric material layer disposed on a surface of the conductive layer substantially opposite to the surface on which the fluorescent material layer is disposed;
a first electrode disposed on the fluorescent material layer; and
a second electrode disposed on the dielectric material layer.

2. The inorganic electroluminescent device of claim 1, wherein at least one of the first electrode and the second electrode is a transparent electrode.

3. The inorganic electroluminescent device of claim 1, wherein the conductive layer comprises at least one of a conductive polymer, silver paste, carbon nano tube paste or a combination thereof.

4. The inorganic electroluminescent device of claim 1, wherein an interface between the conductive layer and the dielectric material layer has a substantially planar surface.

5. The inorganic electroluminescent device of claim 1, wherein the fluorescent material layer is a powder.

6. The inorganic electroluminescent device of claim 5, wherein the fluorescent material layer includes a plurality of granules.

7. The inorganic electroluminescent device of claim 1, wherein a thickness of the conductive layer varies according to a thickness of the fluorescent material layer.

8. The inorganic electroluminescent device of claim 1, wherein the dielectric material layer has a substantially uniform thickness.

9. A display apparatus comprising:
a first electrode array including a plurality of first electrodes arranged in stripe shapes;
a second electrode array including a plurality of second electrodes arranged in stripe shapes extending substantially perpendicular to the plurality of first electrodes of the first electrode array;
a conductive layer interposed between the first electrode array and the second electrode array;
a fluorescent material layer interposed between the conductive layer and the first electrode array; and
a dielectric material layer interposed between the conductive layer and the second electrode array.

10. The display apparatus of claim 9, wherein at least one of the first electrode and the second electrode is a transparent electrode.

11. The display apparatus of claim 9, wherein the conductive layer comprises at least one of a conductive polymer, silver paste, carbon nano tube paste or a combination thereof.

12. The display apparatus of claim 9, wherein an interface between the conductive layer and the dielectric material layer has a substantially planar surface.

13. The display apparatus of claim 9, wherein the fluorescent material layer is a powder.

14. The display apparatus of claim 12, wherein the fluorescent material layer includes a plurality of granules.

15. The display apparatus of claim 9, wherein a thickness of the conductive layer varies according to a thickness of the fluorescent material layer.

16. The display apparatus of claim 9, wherein the dielectric material layer has a substantially uniform thickness.

17. A method of manufacturing an inorganic electroluminescent device, the method comprising:
providing a conductive layer;
disposing a fluorescent material layer on a surface of the conductive layer;
disposing a dielectric material layer on a surface of the conductive layer substantially opposite to the surface on which the fluorescent material layer is disposed;
disposing a first electrode on the fluorescent material layer; and
disposing a second electrode on the dielectric material layer.
